(19) United States
(12) Patent Application Publication
(10) Pub. No.: US 2022/0118760 A1
(43) Pub. Date: Apr. 21, 2022

(54) PRINTHEAD HIGH SIDE SWITCH CONTROLS

(71) Applicant: Hewlett-Packard Development Company, L.P., Spring, TX (US)

(72) Inventors: Eric Thomas Martin, Corvallis, OR (US); Rogelio Cicili, San Diego, CA (US)

(73) Assignee: Hewlett-Packard Development Company, L.P., Spring, TX (US)

(21) Appl. No.: 17/413,687

(22) PCT Filed: Jun. 19, 2019
(86) PCT No.: PCT/US2019/037881

§ 371 Date: Jun. 14, 2021

(51) Int. Cl. B41J 2/045; H03K 3/356; H03K 17/687

(52) U.S. Cl. CPC B41J 2/0455; H03K 3/356104; H03K 2217/0063; B41J 2/04541; B41J 2/0458; H03K 17/6872

(57) ABSTRACT

In example implementations, an apparatus is provided. The apparatus includes a first low voltage control block, a second low voltage control block, a primitive level shifter coupled to the first low voltage control block, a plurality of nozzle level shifters coupled to the primitive level shifter and a second low voltage control block, and a high side switch (HSS) control coupled to each one of the plurality of nozzle level shifters and the second low voltage control block. The plurality of nozzle level shifters are communicatively coupled to each other. The primitive shifter is to enable a selected nozzle level shifter to fire a respective HSS control circuit of the selected nozzle level shifter and to direct a tail current from the selected nozzle level shifter.

### BACKGROUND

Printers are used to print images onto a print medium. Printers may print images using different types of printing fluids and/or materials. For example, some printers may use ink, toner, and the like. A print job may be transmitted to the printer and the printer may dispense the printing fluids and/or materials on the print medium in accordance with the print job.

### BRIEF DESCRIPTION OF THE DRAWINGS

FIG. 1 is a block diagram of a printer that is deployed with an example of the high side switch (HSS) control of the present disclosure;

FIG. 2 is a block diagram of an example nozzle chamber that is controlled by the HSS control of the present disclosure;

FIG. 3 is a block diagram of an example primitive with the HSS control of the present disclosure;

FIG. 4 is a more detailed block diagram to illustrate an example operation of the primitive with the HSS control of the present disclosure; and

FIG. 5 illustrates a flow chart of an example method to activate a thermal ink jet resistor using an HSS control of the present disclosure.

### DETAILED DESCRIPTION

Examples described herein provide a high side switch (HSS) control for a printhead. As discussed above, printers can use various types of systems and printing fluids to print images onto a print medium. One example can be a thermal ink jet (TIJ) printer that uses TIJ printheads. However, the present disclosure may apply to two-dimensional printers as well as three dimensional printers.

A TIJ printhead may include a nozzle chamber that includes a TIJ resistor that can generate heat when energized. The heat generated from the TIJ resistor may heat the printing fluid to create a steam bubble inside of the nozzle chamber that pushes the drop of printing fluid out of the nozzle chamber.

Different types of controls can be used to control activation of the TIJ resistor. Examples of the controls may include a low side switch (LSS) control and a high side switch (HSS) control. The LSS may provide a lower relative cost in terms of an amount of silicon area allocated to the circuits for controlling the LSS and the LSS itself. However, in some cases the LSS may provide no energy regulation against variation in power supply voltage, can have a reduced resistor life due to constant bias between the ink at ground and resistor at a voltage input, and the functionality of an entire group of resistors can be compromised if a single resistor shorts out.

In contrast, the HSS may provide solutions to the above issues with the LSS control. Namely, the HSS may provide energy regulation, some isolation to reduce the bias, and isolate damage to a single resistor if the resistor shorts out. However, the HSS uses a field effect transistor (FET) level shifter that may consume more silicon space, and it may therefore cost more to produce than the LSS. For example, the level shifter can consume as much as thousands of square microns of silicon area per nozzle.

In addition, some HSS control designs can use custom fabricated transistors or devices. These custom devices can make it difficult to efficiently fabricate the HSS controls using standard circuit manufacturing processes in the integrated circuit industry.

The present disclosure provides a circuit design for the HSS control that reduces the amount of silicon that is used by simplifying the level shifter of the HSS control. The simplified level shifter reduces the number of high voltage p-type metal oxide semiconductor (HVPMOS) elements in the level shifter. In addition, the HSS control of the present disclosure uses industry standard devices rather than non-standard devices. As a result, the parts to build the HSS control may be more available and cheaper to build. In addition, the overall amount of silicon that is used is reduced, thereby reducing the overall cost of producing the HSS control of the present disclosure.

Moreover, the present disclosure reduces overall tail currents that can have a detrimental effect on the HSS switches over time. The tail current may be used to bias the level shifters of a primitive for proper operation. The tail current may create thermal efficiency issues in the fluidic die. The fluidic die can include many primitives with many nozzles per primitive. Small amounts of tail current in each nozzle, accumulated over hundreds of primitives and nozzles per fluidic die, can add up to large amounts of static current (e.g., milliamperes of current).

The HSS control of the present disclosure causes the tail current to flow between a firing nozzle level shifter and the primitive level shifter. The tail current is prevented from flowing between non-firing nozzle level shifters and the primitive level shifter. As a result, static tail currents can be reduced.

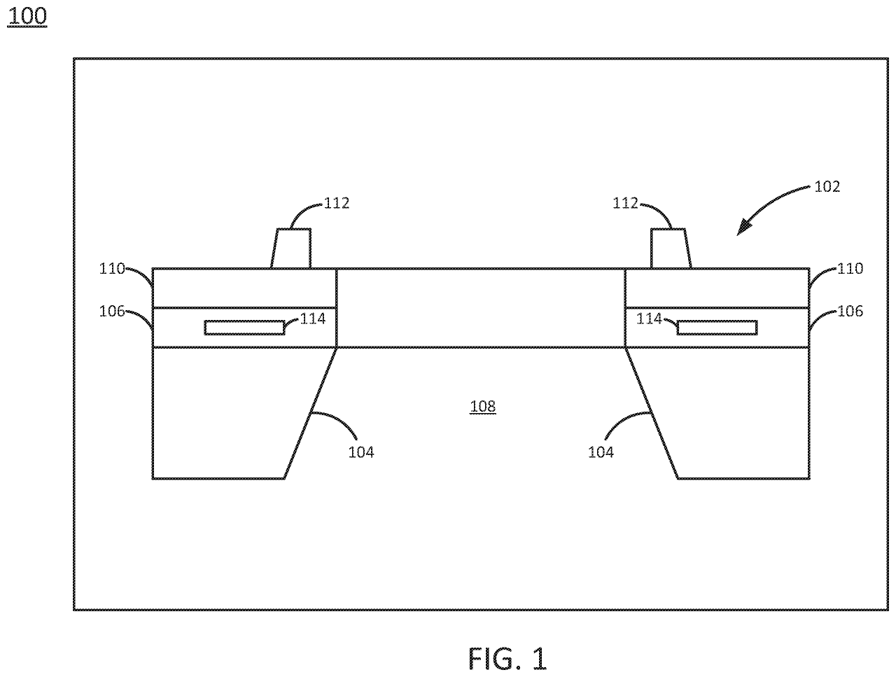

FIG. 1 illustrates an example printer 100 of the present disclosure. In one example, the printer 100 may be a thermal ink jet printer. The printer 100 has been simplified to show a cross-section of a fluidic die 102 used to eject printing fluid onto a print medium. The printer 100 may include additional components that are not shown, such as mechanical components associated with a print path, a feed module, a finishing module, a digital front end, a paper tray, reservoirs for the printing fluid, and the like.

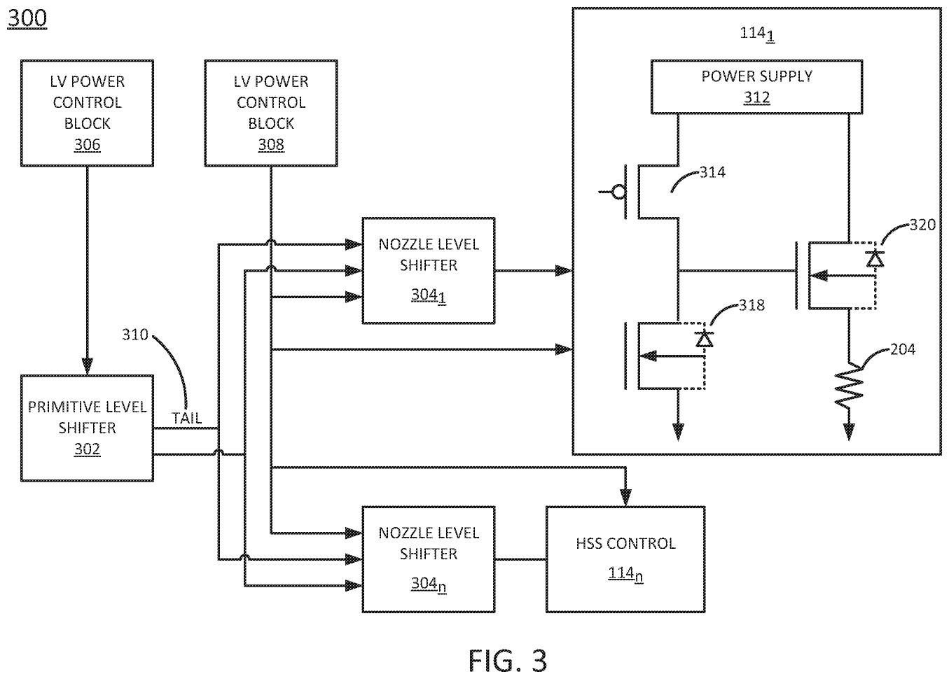

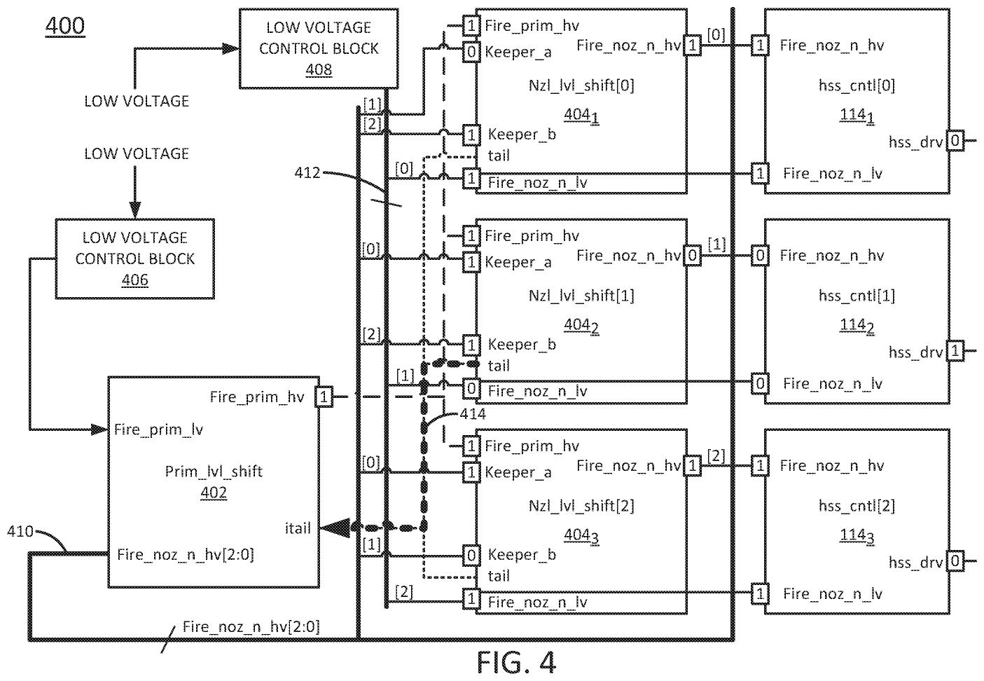

In one example, the fluidic die 102 includes a bulk silicon substrate 104. A layer of circuits 106 may be formed in and/or on the bulk silicon substrate 104. In one example, a high side switch (HSS) circuit block 114 of the present disclosure may be formed on the layer of circuits 106. The HSS circuit block 114 may be used to control the ejection of printing fluid from a nozzle 112 of the fluidic die 102. Each nozzle 112 may be associated with a respective HSS circuit block 114. In other words, the fluidic die 102 may include a plurality of HSS circuit blocks 114. The HSS circuit block 114 of the present disclosure is illustrated in FIGS. 3 and 4 and discussed in further details below.

In one example, the fluidic die 102 may include an ink slot 108 and a layer of fluidics 110. Printing fluid may move through the ink slot 108 to the desired nozzles 112 to be ejected onto a print medium.

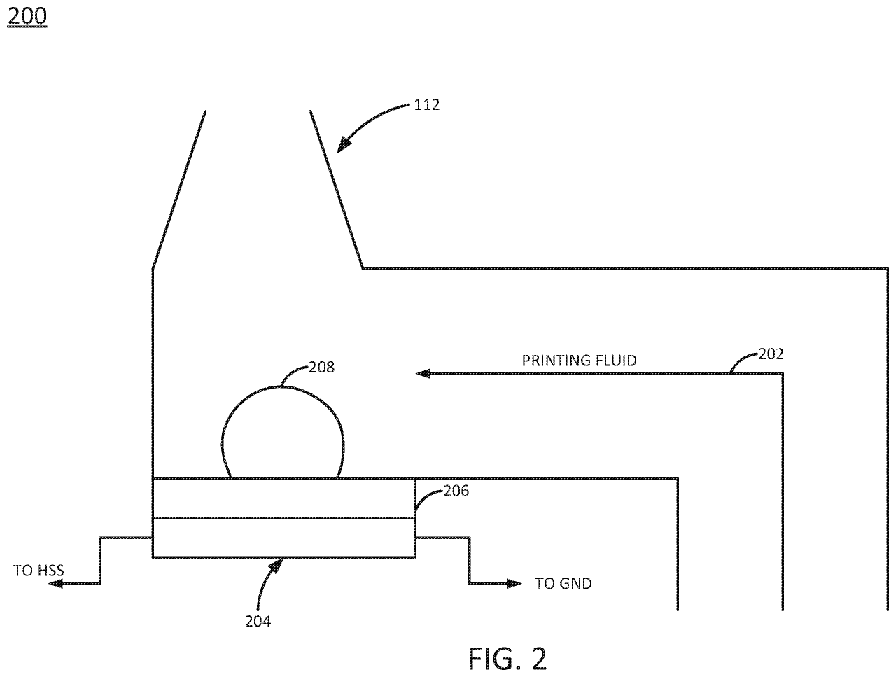

FIG. 2 illustrates a cross sectional view of an example nozzle chamber 200. Each nozzle 112 of the fluidic die 102 may be in fluid communication with a nozzle chamber 200. In one example, the nozzle chamber 200 may be coupled to the HSS circuit block 114. A portion of the nozzle chamber 200 may include a conductive plate 206. The conductive plate 206 may be made of a conductive metal (e.g., tantalum). The conductive plate 206 may be electrically isolated from other components in the nozzle chamber 200.

In one example, a resistor 204 may be positioned adjacent to the conductive plate 206 (also known as a cavitation plate). In one example, an oxide layer may be grown between the resistor 204 and the conductive plate 206. When a printing fluid 202 is provided into the nozzle chamber 200, the resistor 204 may generate heat upon activation to form a steam bubble 208. The steam bubble 208 may force the printing fluid 202 out of the nozzle 112.

The conductive plate 206 may protect the underlying structures from the forces associated with the steam bubble 208 forming and collapsing in the nozzle chamber 200. The conductive plate 206 may also prevent the printing fluid 202 from contacting the resistor 204 and other electrically insulating layers. If the printing fluid 202 were to contact the resistor 204, a short would be formed, which may cause the nozzle chamber 200 to malfunction.

In one example, the HSS circuit block 114 of the present disclosure may be used to control activation of the resistor 204. As noted above, the HSS circuit block 114 of the present disclosure provides a circuit design that is smaller and consumes less silicon in the bulk silicon substrate 104. The design of the HSS circuit block 114 of the present disclosure does not include a circuit clamp and a test circuit, which can consume large amounts of the silicon in the bulk silicon substrate 104. The circuit clamp may be implemented in previous HSS controls to protect susceptible devices from over-voltage events in the case of a fault or defect.

Lastly, the design of the HSS circuit block 114 may use standard components that are not custom built, and therefore, more compatible with available manufacturing processes. As a result, the cost to build the HSS circuit block 114, and the overall fluidic die 102 may be significantly reduced.

Although an example of an ejecting actuator is illustrated in FIG. 2, it should be noted that the HSS circuit block 114 can also be used to control non-ejecting actuators (e.g., actuators that use micro-fluidic pumps). For example, the HSS circuit block 114 may be used to generate the steam bubble 208 that can be used to move fluid through a channel.

FIG. 3 illustrates a block diagram of an example primitive 300 of the present disclosure. Although a single primitive 300 is illustrated in FIG. 3, it should be noted that a plurality of primitives may be communicatively coupled to one another via a communication bus.

In one example, the primitive 300 includes a primitive level shifter 302, a plurality of nozzle level shifters 304₁-304ₙ (hereinafter also referred to individually as a nozzle level shifter 304 or collectively as nozzle level shifters 304), and a plurality of HSS circuit blocks 114₁ to 114ₙ.

In one example, a low voltage control block 306 may be communicatively coupled to the primitive level shifter 302. The low voltage control block 306 may be controlled by a low voltage power source to generate low voltage signals. For example, the low voltage power source may provide low voltage (e.g., 0-5 volts or 0-3.3 volts) to the low voltage control block 306. The low voltage control block 306 may generate a low voltage logic signal. For example, the low voltage logic signal may be an enable or activate signal (e.g., a logic 1) or a disable or deactivate signal (e.g., a logic 0).

In one example, a second low voltage control block 308 may be communicatively coupled to the nozzle level shifters 304. The second low voltage control block 308 may be similar to the low voltage control block 306 and may also be powered by a low voltage power source (e.g., 0-5 volts or 0-3.3 volts). The second low voltage control block 308 may generate a low voltage logic signal. For example, the low voltage logic signal generated by the second low voltage control block 308 may be an enable or activate signal (e.g., a logic 1) or a disable or deactivate signal (e.g., a logic 0).

In some examples, the nozzle level shifters 304 may be operated based on an inverse of the signal received from the second low voltage control block 308. For example, the nozzle level shifter 304 may be fired in response to the receipt of the digital signal of 0, or may be kept off in response to receipt of a digital signal of 1.

In one example, each nozzle level shifter 304 may be coupled to a respective HSS circuit block 114. FIG. 3 illustrates an example of the HSS circuit block 114. In one example, the HSS circuit block 114 may include a power supply 312. The power supply 312 may be a high voltage power supply that provides 10 volts or more. In some examples, the high voltage power supply may provide 30 volts or higher. Although a single power supply 312 is illustrated in FIG. 3, it should be noted that two separate power supplies 312 may be implemented to trade off different levels of voltage regulation for power and thermal efficiency. For example, a first power supply may be independently coupled to a switch 314 (described below) and a second power supply may be coupled to a switch 320 (described below).

In one example, a high voltage p-type metal oxide semiconductor (HVPMOS) switch 314 may be coupled to the power supply 312. The power supply 312 may be a high power voltage supply, such as a 30 V power supply. The HVPMOS switch 314 may be a high voltage switch that may be controlled via a high voltage signal (e.g., from the nozzle level shifter 304, as illustrated in FIG. 4, and discussed in further details below). The gate of the HVPMOS switch 314 may operate between a high voltage and the high voltage less the voltage provided from a single gate laterally diffused metal oxide semiconductor (SGLDMOS) switch 318. For example, if the SGLDMOS switch 318 operates at approximately 3.3 volts, the gate of the HVPMOS switch 314 may be activated with 27 volt signal or deactivated with a 30 volt signal.

In one example, the SGLDMOS switch 318 may be coupled downstream from the HVPMOS switch 314 The SGLDMOS switch 318 may be a high voltage switch that is controlled via a low voltage signal (e.g., from the second low voltage control block 308, as illustrated in FIG. 4, and discussed in further details below). The SGLDMOS switch 318 may be activated with a 3.3 volt signal and deactivated with a 0 volt signal.

In one example, a laterally diffused metal oxide semiconductor (LDMOS) switch 320 may be coupled to the power supply 312. The LDMOS switch 320 may be an n-type switch that can be controlled with a high voltage signal (e.g., the gate of the switch 320 may transition between 0-30 volts). The LDMOS switch 320 may be an efficient switch for controlling the heat resistor 204.

The heat resistor 204 may be coupled to the LDMOS switch 320. When the LDMOS switch 320 is activated, current may flow across the LDMOS switch 320 to the heat resistor 204. The heat resistor 204 may generate heat as current flows through the heat resistor 204 to create the steam bubble 208, which causes the printing fluid 202 to be ejected from the nozzle chamber 200.

In one example, the HVPMOS switch 314 and the SGLDMOS switch 318 may operate in an inverse relationship to control activation of the LDMOS switch 320. For example, when the LDMOS switch 320 is activated, and the SGLDMOS switch 318 is deactivated, the LDMOS switch 320 may be activated to draw 30 volts from the power supply 312. When the LDMOS switch 320 is activated, the LDMOS switch 320 may couple the heat resistor 204 to the power supply 312 to allow current to flow through the LDMOS switch 320 and to the heat resistor 204. The current flowing through the heat resistor 204 may cause the heat resistor 204 to generate heat, form the steam bubble 208, and eject the printing fluid 202, as described above.

In one example, when the HVPMOS switch 314 is deactivated and the SGLDMOS switch 318 is activated, the LDMOS switch 320 may be deactivated. In other words, the LDMOS switch 320 may decouple the power supply 312 from the resistor 204. As a result, no current flows through the LDMOS switch 320 to the heat resistor 204, which turns off the heat resistor 204.

In one example, the primitive level shifter 302 may control operation or firing of the nozzle level shifters 304₁ to 304ₙ, which in turn may control operation of the HSS circuit blocks 114₁ to 114ₙ. For example, the primitive level shifter 302 may receive an enable signal (e.g., approximately 3.3. volts from the low voltage control block 306) for the nozzle level shifter 304₁ in response to the nozzle level shifter 304₁ being selected to fire. At the same time a logic low signal (e.g., a digital signal of 0) may be received by the nozzle level shifter 304₁ from the second low voltage control block 308.

In one example, the primitive level shifter 302 may also direct a tail current (tail or itail) 310 from the nozzle level shifter 304₁ that is selected to fire. Thus, rather than accumulating the tail current 310 inside of the nozzle level shifter 304₁, the tail current can be redirected out of the primitive 300. The primitive 300 may be designed to redirect the tail current 310 from the nozzle level shifter 304₁ that is selected and into the primitive level shifter 302. Similarly, if the nozzle level shifter 304ₙ and the HSS circuit block 114ₙ were selected to fire, the primitive level shifter 302 may direct the tail current 310 from the nozzle level shifter 304ₙ out to the primitive level shifter 302. If no nozzle level shifter 304 is selected to fire, then the tail current 310 may be sourced and sunk inside the primitive level shifter 302.

Moreover, the primitive 300 may be implemented with low voltage control blocks, which reduces overall cost. In addition, the structure of the primitive 300 reduces the total number of high voltage devices used in the primitive level shifter 302, the nozzle level shifters 304, and the HSS circuit blocks 114 per primitive 300. This may also reduce costs. Thus, the primitive 300 may be cheaper to produce, while reducing total tail current on the fluidic die 102, which may make the fluidic die 102 more energy and thermally efficient.

FIG. 4 illustrates a more detailed block diagram to illustrate an example operation of a primitive 400. The primitive 400 is illustrated to include three nozzle level shifters 404₁-404₃ (also referred to as Nzl_lvl_shift [0]-[2]). Each nozzle level shifter 404 may be coupled to a respective HSS control block 114₁-114₃ (also referred to as hss_cntl [0]-[2]).

FIG. 4 illustrates additional details related to signal inputs and outputs of a primitive level shifter 402, nozzle level shifters 404₁ to 404ₙ (hereinafter referred to individually as a nozzle level shifter 404 or collectively as nozzle level shifters 404), and the HSS circuit blocks 114. The HSS circuit blocks 114 may be implemented similar to the HSS circuit blocks 114 illustrated in FIG. 3 and described above. FIG. 4 illustrates an example of operation and the associated digital signals for various inputs/outputs in response to the nozzle shifter 404₂ (e.g., nzl_lvl_shift[1]) being selected to fire.

In one example, the primitive level shifter 402 may include a fire_prim_lv input, a fire_noz_n_hv input, a fire_prim_hv output, and a tail current (itail) input. In one example, the primitive level shifter 402 may include a high voltage portion and a low voltage portion. For example, a portion of the primitive level shifter 402 may generate the high voltage signal fire_prim_hv. The high voltage portion of the primitive level shifter 402 may be implemented with low voltage p-type or n-type CMOS field effect transistors (FETs). These FETs may be controlled by and switched by low differential voltages (e.g., 0-3.3 volts or 0-5 volts) between their terminals (e.g., the gates, drains, and sources of the respective FETs). However, the FETs may operate on high voltage rails. For example, whereas the FETs may normally operate on 0-5 volt rails, the FETs in the present disclosure may operate on 25-30 volt rails. By using low voltage devices, but at a shifted low-differential voltage rail, the circuitry uses significantly less area, and is therefore lower in cost to produce. The low voltage portion of the primitive level shifter 402 may receive and process the low voltage signal fire_prim_lv.

In one example, each nozzle level shifter 404 may include a fire_prim_hv input, a keeper_a input, a keeper_b input, a tail current output, a fire_noz_n_lv input, and a fire_noz_n_hv output. In one example, similar to the primitive level shifter 402, there may be a high-voltage and low-voltage portion of each nozzle level shifter 404. While the high-voltage and the low-voltage portions both may use, in part, low-voltage n-type and p-type CMOS devices, those devices operate on different voltage rails. For example, the CMOS FETs in the low-voltage portion may operate on 0-5 volt rails and the CMOS FETs in the high-voltage portion may operate on 25-30 volt rails. Notably both rails are low voltage ranges (e.g., 5 volt range).

In the nozzle level shifters 404, the fire_noz_n_lv may control circuits in the low voltage portion and the fire_prim_hv and keeper signals may control circuits in the high voltage portion. The number of keeper inputs may be one less than the number of nozzle level shifters 404 in the primitive 400.

Similarly, the keeper signals may include any number of keeper signals that are equal to the total number of nozzle level shifters 404 minus one. Thus, if there were 8 nozzle level shifters 404, then each nozzle level shifter 404 may have 7 keeper signals.

FIG. 4 illustrates a multi-bit bus 410 that branches off into single bit lines for the keeper_a and keeper_b inputs. The keeper inputs may receive a firing status from other nozzle level shifters. The fire_noz_n_hv output may send a high voltage signal to indicate the firing status of a respective nozzle level shifter to a respective keeper input of the other nozzle level shifters.

As shown in FIG. 4, each nozzle level shifter 404 may receive as inputs keeper signals from all other nozzle level shifters 404 except its own. For example, the nozzle level shifter 404₁ may receive input keeper signals from the nozzle level shifters 404₂ and 404₃ via the output of the respective fire_noz_n_hv outputs, but not from itself. Specifically, the value of the keeper_a and keeper_b for each nozzle level shifter 404 may be the fire_noz_n_hv output of other nozzle level shifters 404. For example, nozzle level shifter 404₁ is associated with bit 0. Thus, the value of the keeper_a and keeper_b inputs are associated with bits 1 and 2. The nozzle level shifter 404₂ is associated with bit 1. Thus, the value of the keeper_a and keeper_b inputs are associated with bits 0 and 2. The nozzle level shifter 404₃ is associated with bit 2. Thus, the value of the keeper_a and keeper_b inputs are associated with bits 0 and 1.

The function of the keeper signals may be to ensure that when the fire_noz_n_hv output of a nozzle level shifter 404 is active (e.g., logic value of 0), the fire_noz_n_hv output of all other nozzle level shifters 404 are inactive (e.g., a logic value of 1). So in the present example and in FIG. 4, when the fire_noz_n_hv output of the nozzle level shifter 404₂ is active, that signal being tied to a keeper pin of the other nozzle level shifters 404₁ and 404₃ may cause the fire_noz_n_hv outputs of the nozzle level shifters 404₁ and 404₃ to be inactive. In other words, the non-selected nozzle level shifters (e.g., 404₁ and 404₃) may be disabled in response to any one of the keeper_a and keeper_b inputs being set to an active state (e.g., a logic value of 1). If no nozzle is firing, then no keeper signals will cause the fire_noz_n_hv outputs to be inactive. However, in that case the fire_prim_hv may be 0 for all of the nozzle level shifters 404, which may cause the fire_noz_n_hv output to be inactive for all nozzle level shifters 404.

In one example, the fire_noz_n_hv output of each one of the nozzle level shifters 404 may also be sent to the fire_noz_n_hv input of the primitive level shifter 402. The signal from the fire_noz_n_hv output may be transmitted over the multi-bit bus 410. Based on the fire_noz_n_hv signal from each nozzle level shifter 404, the primitive level shifter 402 may know which nozzle level shifters 404 are firing or active and which nozzle level shifters 404 are not firing or inactive.

In one example, each HSS circuit block 114 may include a fire_noz_n_hv input, a fire_noz_n_lv input, and an HSS_dry output. In one example, the fire_noz_n_hv input may be a digital signal that drives the gate of the HVPMOS switch 314 illustrated in FIG. 3 and described above. The digital signal for the fire_noz_n_hv input may be provided by the fire_noz_n_hv output of the nozzle level shifters 404. The fire_noz_n_lv input may be a digital signal that drives the gate of the SGLDMOS switch 318 illustrated in FIG. 3 and described above. The digital signal for the fire_noz_n_lv input may be provided by the second low voltage control block 408. The hss_dry signal may be a signal that drives the gate of the LDMOS switch 320 illustrated in FIG. 3 and described above.

The primitive 400 may include a first low voltage control block 406 and a second low voltage control block 408. The first low voltage control block 406 and the second low voltage control block 408 may be powered by a low voltage power source (e.g., 3.3 volts or 5 volts). The first low voltage control block 406 and the second low voltage control block 408 may generate low-voltage logic signals that transition between 0-5 volts or 0-3.3 volts, for example.

In one example, the nozzle level shifter 404₂(nzl_lvl_shift[1]) may be selected to fire. The low voltage control block 406 may send a digital signal of 1 to the fire_prim_lv input of the primitive level shifter 402. The primitive level shifter 402 may generate a digital signal of 1 and transmit the digital signal of 1 to the fire_prim_hv input of the nozzle level shifters 404₁-404₃ to indicate that a nozzle in the primitive is firing.

At the same time, the second low voltage control block 408 may provide a second signal (e.g., the fire_noz_n_lv signal) to the nozzle level shifters 404₁-404₃. The second low voltage control block 408 may drive a multi-bit bus 412 that can transmit different digital values for different bits associated with the nozzle level shifters 404. For example, to indicate that the nozzle level shifter 404₂ is to fire, the second low voltage control block 408 may transmit a digital value of 1 for bit 0 associated with the nozzle level shifter 404₁, transmit a digital value of 0 for bit 1 associated with the nozzle level shifter 404₂, and transmit a digital value of 0 for bit 2 associated with the nozzle level shifter 404₃.

As noted above, the first signal from the first low voltage control block 406 and the second signal from the second low voltage control block 408 may be inversely related. For example, an enable signal or 1 from the first low voltage control block 406 and a disable signal or 0 from the second low voltage control block 408 may enable the selected nozzle level shifter 404₂ to fire the respective HSS circuit block 114₂. When, the nozzle level shifter 404₂ is selected to fire, the primitive level shifter 402 may transmit the fire_noz_n_hv signal of 0 to the nozzle level shifter 404₂ and the HSS circuit block 114₂. The fire_noz_n_hv signal for the nozzle level shifter 404₁ and 404₃ may be set to 1. As noted above, the fire_noz_n_hv may be a high voltage signal to control the gate of the HVPMOS switch 314 of the HSS circuit block 114₂.

In addition, the second signal from the second low voltage control block 408 may be transmitted to the fire_noz_n_lv input of the HSS circuit block 114₂ from the nozzle level shifter 404₁. The fire_noz_n_lv signal may be the low voltage signal to control the gate of the SGLDMOS switch 318 of the HSS circuit block 114₂. With the fire_noz_n_hv signal from the selected nozzle level shifter 404₂ and the fire_noz_n_lv signal from the second low voltage control block 408, the HSS circuit block 114₂ may generate the HSS_dry signal to control the gate of the LDMOS 320 and pass current through the resistor 204.

When the nozzle level shifter 404₂ is selected to fire, the tail current may flow from the selected nozzle level shifter 404₂ (e.g., the tail output) and into the primitive level shifter 402 (e.g., the itail input), as shown by arrow 414. The selected nozzle level shifter 404₂ may then communicate back to the primitive level shifter 402 and the other unselected, or remaining nozzle level shifters 404₁ and 404₃ through the fire_noz_n_hv output. For example, the selected nozzle level shifter 404₂ may send a signal from its fire_noz_n_hv output to the keeper inputs of the nozzle level shifters 404₁ and 404₃, which may cause the fire_noz_n_hv outputs of the nozzle level shifters 404₁ and 404₃ to remain inactive and prevent them from firing.

Similarly, the keeper input associated with the bit 1 (e.g., the bit associated with the nozzle level shifter 404₂) for the nozzle level shifters 404₁ and 404₃ may be set to an active state or a logic value of 0 to indicate that the nozzle level shifter 404₂ is firing. Thus, if any keeper input is set to an active state (e.g., a value of 0) for a particular nozzle level shifter, the respective fire_noz_n_hv for that nozzle level shifter may be disabled and set to a value of 1.

The connections between the fire_noz_n_hv outputs and the keeper inputs of the nozzle level shifters 404 may help the nozzle level shifters 404 to communicate with one another to ensure that one nozzle level shifter fires at a time. Thus, the tail current can be appropriately steered from the firing nozzle.

In one example, when no nozzle level shifter 404 is selected to fire, the first low voltage control block 406 may transmit a disable signal or a digital signal of 0 to the fire_prim_lv input of the primitive level shifter 402. At the same time, the second low voltage control block 408 may transmit a digital signal of 1 to the fire_noz_n_lv input of the nozzle level shifters 404. The digital signal of 0 at the fire_prim_lv of the primitive level shifter 402 may cause the fire_prim_hv signal to be set to an inactive state and generate a digital signal of 0. When the fire_prim_hv signal is set to a value of 0, the fire_noz_n_hv inputs for the nozzle level shifters 404 and the HSS control circuits 114 may also be set to a value of 1. Additionally, the fire_prim_hv input being set to a value of 0 may cause the tail current to flow internal to the primitive level shifter 402, and not between the primitive level shifter 402 and the nozzle level shifters 404.

Thus, the primitives 300 and 400 of the present disclosure provides a design that reduces tail currents within the primitive by directing the tail currents to a nozzle level shifter that is selected to fire. In addition, the design uses low voltage switches to internally generate a high voltage signal that can be used to control the high voltage switch within the HSS circuit block 114. As a result, the overall design of the primitives 300 and 400 reduces the number of high voltages switches that are used and reduces the overall manufacturing costs.

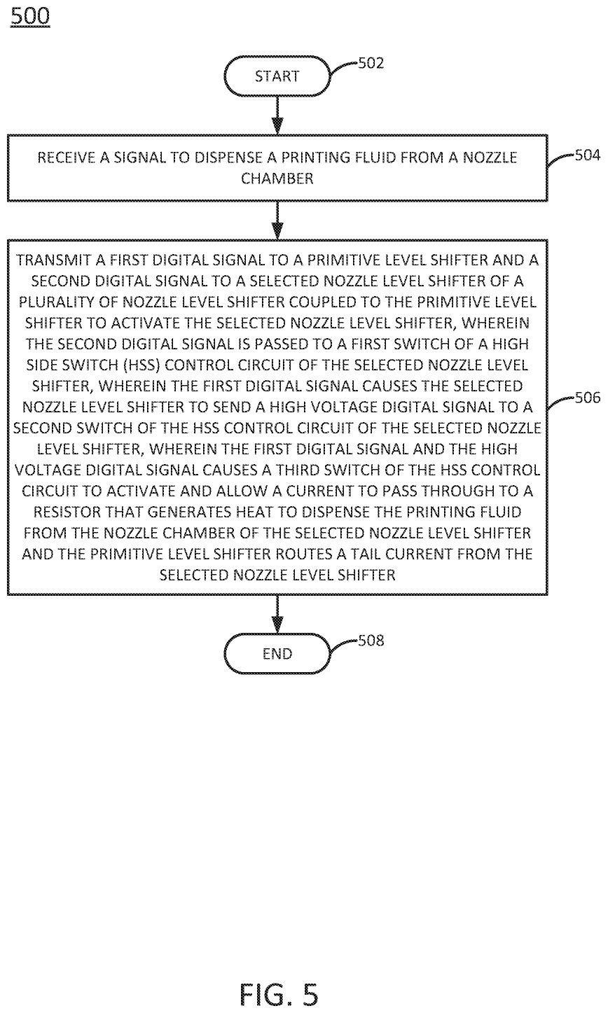

FIG. 5 illustrates a flow chart of an example method to activate a thermal ink jet resistor using an HSS control of the present disclosure. In an example, the method 500 may be performed by a controller or processor of the printer 100 illustrated in FIG. 1.

At block 502, the method 500 begins. At block 504, the method 500 receives a signal to dispense a printing fluid from a nozzle chamber. For example, a printer may be activated to print a desired image onto a print medium. The printer may determine locations on the print medium to dispense a printing fluid. The printing fluid may be dispensed via nozzle chambers in a fluidic die.

At block 506, the method 500 transmits a first digital signal to a primitive level shifter and a second digital signal to a selected nozzle level shifter of a plurality of nozzle level shifters coupled to the primitive level shifter to activate the selected nozzle level shifter, wherein the second digital signal is passed to a first switch of a high side switch (HSS) control circuit of the selected nozzle level shifter, wherein the first digital signal causes the selected nozzle level shifter to send a high voltage digital signal to a second switch of the HSS control circuit of the selected nozzle level shifter, wherein the first digital signal and the high voltage digital signal causes a third switch of the HSS control circuit to activate and allow a current to pass through to a resistor that generates heat to dispense the printing fluid from the nozzle chamber of the selected nozzle level shifter and the primitive level shifter routes a tail current from the selected nozzle level shifter. For example, the primitive level shifter can redirect the tail current from the nozzle level shifter that is selected to fire. In addition, the heat generated by the current flowing through the resistor of the HSS control circuit may cause a steam bubble to form inside of the nozzle chamber. The steam bubble may force the printing fluid through the nozzle and out of the nozzle chamber onto the print media.

In one example, a signal to stop the printing fluid from dispensing from the nozzle chamber may be received. For example, printing may be completed at a particular location of the print media for the print job.

In response to the signal to stop the printing fluid from dispensing, the printer may cause the first digital signal to the primitive level shifter and the second digital signal to the selected nozzle level shifter to be removed to deactivate the HSS control circuit. When the HSS control circuit is deactivated, current is prevented from flowing through the resistor of the HSS control circuit and the tail current is removed from the selected nozzle level shifter. At block 508, the method 500 ends.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
a first low voltage control block;
a second low voltage control block;
a primitive level shifter coupled to the first low voltage control block; and
a plurality of nozzle level shifters coupled to the primitive level shifter and the second low voltage control block, wherein the plurality of nozzle level shifters are communicatively coupled to each other; and
a high side switch (HSS) control circuit coupled to each one of the plurality of nozzle level shifters and the second low voltage control block, wherein the primitive level shifter is to enable a selected nozzle level shifter to fire a respective HSS control circuit of selected nozzle level shifter and to direct a tail current from the selected nozzle level shifter.

2. The apparatus of claim 1, wherein the first low voltage control block is powered by a low voltage power source to generate a low voltage logic signal.

3. The apparatus of claim 1, wherein the selected nozzle level shifter to fire in response to a signal from the primitive level shifter and a signal from the second low voltage control block.

4. The apparatus of claim 1, wherein the respective HSS control circuit is to be activated in response to a first signal from the second low voltage control block and a second signal from the selected nozzle level shifter.

5. The apparatus of claim 4, wherein the first signal and the second signal are inversely related.

6. The apparatus of claim 1, wherein the selected nozzle level shifter is to provide a signal to remaining nozzle level shifters of the plurality of nozzle level shifters to prevent the remaining nozzle level shifters from firing.

7. An apparatus, comprising:
a first low voltage control block;
a second low voltage control block;
a primitive level shifter, the primitive level shifter comprising:
a fire_prim_lv input to receive a digital signal from the first low voltage control block;
a fire_prim_hv output to output an enable signal to enable a selected nozzle level shifter to fire; and
a tail input to receive a tail current from the selected nozzle level shifter;
a plurality of nozzle level shifters coupled to the primitive level shifter and the second low voltage control block, wherein each one of the plurality of nozzle level shifters comprises:
a fire_prim_hv input to receive the enable signal from the primitive level shifter;
a plurality of keeper inputs to receive a firing status from other nozzle level shifters;
a tail output to direct the tail current to the primitive level shifter when selected to fire; and
a fire_noz_n_hv output to send a provide a high voltage signal to indicate the firing status of a respective nozzle level shifter to a respective keeper input of the other nozzle level shifters; and
a plurality of high side switch control circuits coupled to each one of the plurality of nozzle level shifters and the second low voltage control block.

8. The apparatus of claim 7, wherein the plurality of keeper inputs comprises a number of the plurality of nozzle level shifters minus one.

9. The apparatus of claim 8, wherein the plurality of keeper inputs are each associated with a value of a bit associated with other nozzle level shifters.

10. The apparatus of claim 7, wherein non-selected nozzle level shifters of the plurality of nozzle level shifters are disabled in response to any one of the plurality of keeper inputs being set to an active state.

11. The apparatus of claim 7, wherein the plurality of nozzle level shifters are disabled in response to the fire_prim_hv output of the primitive level shifter is set to an inactive state.

12. The apparatus of claim 7, wherein the plurality of nozzle level shifters comprises a high voltage portion and a low voltage portion

13. The apparatus of claim 7, wherein the primitive level shifter comprises a high voltage portion and a low voltage portion.

14. A method comprising:
receiving, by a processor, a signal to dispense a printing fluid from a nozzle chamber; and
transmitting, by the processor, a first digital signal to a primitive level shifter and a second digital signal to a selected nozzle level shifter of a plurality of nozzle level shifter coupled to the primitive level shifter to activate the selected nozzle level shifter, wherein the second digital signal is passed to a first switch of a high side switch (HSS) control circuit of the selected nozzle level shifter, wherein the first digital signal causes the selected nozzle level shifter to send a high voltage digital signal to a second switch of the HSS control circuit of the selected nozzle level shifter, wherein the first digital signal and the high voltage digital signal causes a third switch of the HSS control circuit to activate and allow a current to pass through to a resistor that generates heat to dispense the printing fluid from the nozzle chamber of the selected nozzle level shifter and the primitive level shifter routes a tail current from the selected nozzle level shifter.

15. The method of claim 14, further comprising:
receiving, by the processor, a signal to stop the printing fluid from dispensing from the nozzle chamber; and
removing, by the processor, the first digital signal to the primitive level shifter and the second digital signal to the selected nozzle level shifter to deactivate the HSS to prevent current from flowing through the resistor and to remove the tail current from the selected nozzle level shifter.
